(19) United States
(12) Patent Application Publication
(10) Pub. No.: US 2013/0068304 A1
(43) Pub. Date: Mar. 21, 2013

(54) SEALING MATERIAL, SOLAR CELL MODULE, AND LIGHT-EMITTING DIODE

(71) Applicants: Takayuki Kanematsu, Sakura-shi (JP); Naoto Yagi, Sakura-shi (JP); Hisashi Tanimoto, Sakura-shi (JP); Tomoko Shishikura, Sakura-shi (JP)

(72) Inventors: Takayuki Kanematsu, Sakura-shi (JP); Naoto Yagi, Sakura-shi (JP); Hisashi Tanimoto, Sakura-shi (JP); Tomoko Shishikura, Sakura-shi (JP)

(73) Assignee: DIC CORPORATION, Tokyo (JP)

(21) Appl. No.: 13/577,690

(22) PCT Filed: May 24, 2011
(86) PCT No.: PCT/JP2011/061841

§ 371 Date: Oct. 19, 2012

(30) Foreign Application Priority Data
Jun. 8, 2010 (JP) 2010-130930

(51) Int. Cl. C08L 83/10; H01L 33/56; H01L 31/0203

(52) U.S. Cl. 136/259; 257/100; 525/450; 257/E33.059

(57) ABSTRACT

There is provided a sealing material including a composite resin (A) including a polysiloxane segment (a1) having a structural unit represented by general formula (1) and/or general formula (2) and a silanol group and/or a hydrolyzable silyl group and a vinyl-based polymer segment (a2) having an alcoholic hydroxyl group, the vinyl-based polymer segment (a2) being bonded to the polysiloxane segment (a1) through a bond represented by general formula (3), and a polyisocyanate (B), wherein the content of the polysiloxane segment (a1) is 10% to 50% by weight relative to the total solid content of a curable resin composition, and the content of the polyisocyanate (B) is 5% to 50% by weight relative to the total solid content of the curable resin composition. There are also provided a solar cell module and a light-emitting diode that each use the sealing material.

### TECHNICAL FIELD

The present invention relates to a sealing material for various devices and particularly to a sealing material for light-emitting diodes and a sealing material for solar cells that are used in an environment in which they are constantly exposed to light.

### BACKGROUND ART

In recent years, a transparent resin that transmits light has been used as a sealing material to protect various devices. Examples of light-emitting diodes (LEDs) practically used for display boards, light sources for reading images, traffic lights, large display units, backlight of cellular phones, and the like include a light-emitting diode obtained by combining a phosphor with a light-emitting diode that emits blue light to ultraviolet light, such as a GaN (gallium nitride)-based light-emitting diode, and a light-emitting diode obtained by combining a red light-emitting diode, a blue light-emitting diode, and a yellow light-emitting diode with each other. In these light-emitting diodes, a compound semiconductor chip and an electrode are normally sealed with a transparent resin for the purpose of their protection. An epoxy resin, specifically a resin obtained by adding an alicyclic acid anhydride as a curing agent to an aromatic epoxy resin, is generally used as the transparent resin. However, it is known that, in such a resin, an acid anhydride is easily discolored due to an acid and it takes a long time for curing. Furthermore, when a cured sealing resin is left in the open air or exposed to a light source that emits ultraviolet rays, there are problems in that the sealing resin becomes brittle and turns yellow.

In other words, when light-emitting diodes emit ultraviolet light or are used in the open air, part of the skeleton of the epoxy resin serving as a sealing material is broken or the epoxy resin turns yellow due to its aromatic ring. Consequently, a coloring phenomenon in which yellowing gradually proceeds occurs from a portion around a light-emitting diode chip, which limits the life of a light-emitting device.

Such a transparent resin that transmits light has been also used as a sealing material for solar cells in which sunlight is directly converted into electric energy.

Solar cell modules generally have a structure in which a solar cell such as a power generating silicon element is sealed with a sealing material such as an EVA (ethylene-vinyl acetate copolymer, which is generally a mixture with an organic peroxide) film between a light-receiving-side transparent protective member and a backside protective member. Such a solar cell module is produced by stacking a light-receiving-side transparent protective member, a sheet-shaped sealing material disposed on the surface side of the solar cell module, a solar cell, a sheet-shaped sealing material disposed on the backside of the solar cell module, and a backside protective member in that order and by performing heating under pressure to cure the EVA through crosslinking and bond the above components to each other for integration.

Since such a solar cell module is also used in the open air, components used in the module need to have high durability and high weather resistance. In particular, in a sealing material for solar cells, an ultraviolet absorber is generally added to the entire sealing material in a uniform manner to prevent the embrittlement and yellowing of the sealing material during long-term use. However, since the sealing material is thick, a considerably large amount of ultraviolet absorber needs to be added to produce the effects of the ultraviolet absorber, resulting in an increase in cost.

It is known that a siloxane resin is used as a resin for such sealing materials. For example, a silsesquioxane derivative is used as the sealing material for light-emitting diodes (e.g., refer to PTL 1). An example of the sealing material for solar cells is described below. A resin composition prepared by mixing a base resin composed of a siloxane polymer modified with a methyl group and a phenyl group with at least one organic metal compound serving as a curing agent is applied onto the surface of an adherend composed of a plastic substrate and a metal electrode and cured by performing heating (e.g., refer to PTL 2).

### CITATION LIST

### Patent Literature

PTL 1: Japanese Unexamined Patent Application Publication No. 2009-167390
PTL 2: Japanese Unexamined Patent Application Publication No. 2009-215345

### SUMMARY OF INVENTION

### Technical Problem

It is an object to provide a highly weather-resistant sealing material for various devices that does not easily turn yellow or generate cracks even after long-term exposure with ultraviolet rays in the open air or the like. It is another object to provide a solar cell module and a light-emitting diode that each use the sealing material.

### Solution to Problem

As a result of thorough studies, the inventors of the present invention have found that a curable resin composition prepared by adding, in a certain range, a polyisocyanate to a composite resin having a polysiloxane segment having a silanol group and/or a hydrolyzable silyl group and a polymerizable double bond and a segment of a polymer other than the polysiloxane has long-term weather resistance in the open air, for example, crack resistance and light resistance. Thus, the objects above have been achieved.

By adjusting the content of the polysiloxane segment in the curable resin composition in a certain range, even a cured product obtained by being cured using an active energy ray such as ultraviolet rays without being heated to high temperature has high durability, and the relaxation of stress generated due to a change in temperature can be achieved.

The present invention provides a sealing material including a composite resin (A) including a polysiloxane segment (a1) having a structural unit represented by general formula (1) and/or general formula (2) and a silanol group and/or a hydrolyzable silyl group and a vinyl-based polymer segment (a2) having an alcoholic hydroxyl group, the vinyl-based polymer segment (a2) being bonded to the polysiloxane segment (a1) through a bond represented by general formula (3), and a polyisocyanate (B), wherein the content of the polysiloxane segment (a1) is 10% to 50% by weight relative to the total solid content of a curable resin composition, and the content of the polyisocyanate (B) is 5% to 50% by weight relative to the total solid content of the curable resin composition:

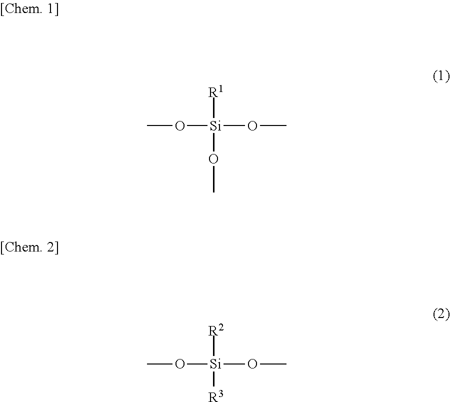

(in the general formulae (1) and (2), R¹, R², and R³ each independently represent a group having a polymerizable double bond selected from the group consisting of —R⁴—CH═CH₂, —R⁴—C(CH₃)═CH₂, —R⁴—O—CO—C(CH₃)═CH₂, and —R⁴—O—CO—CH═CH₂ (R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms, and at least one of R¹, R², and R³ represents the group having a polymerizable double bond),

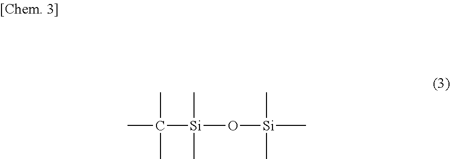

(in the general formula (3), a carbon atom constitutes a part of the vinyl-based polymer segment (a2) and a silicon atom bonded to only an oxygen atom constitutes a part of the polysiloxane segment (a1)).

The present invention also provides a solar cell module that uses the sealing material.

The present invention also provides a light-emitting diode that uses the sealing material.

### Advantageous Effects of Invention

The sealing material of the present invention has high weather resistance and thus yellowing and cracking are not easily caused even after long-term exposure with ultraviolet rays in the open air or the like. The solar cell module that uses the sealing material of the present invention has long-term weather resistance such as high light resistance and crack resistance. The light-emitting diode that uses the sealing material of the present invention has not only long-term weather resistance but also heat resistance and wet heat resistance.

### BRIEF DESCRIPTION OF DRAWINGS

FIG. 1 shows an example of a superstrate solar cell module.

FIG. 2 shows a container into which a sealing material is injected.

FIG. 3 shows a light-emitting diode produced in Examples.

### DESCRIPTION OF EMBODIMENTS

### (Composite Resin (A))

The composite resin (A) used in the present invention is a composite resin (A) including a polysiloxane segment (a1) having a structural unit represented by the general formula (1) and/or the general formula (2) and a silanol group and/or a hydrolyzable silyl group (hereinafter simply referred to as polysiloxane segment (a1)) and a vinyl-based polymer segment (a2) having an alcoholic hydroxyl group (hereinafter simply referred to as vinyl-based polymer segment (a2)), the vinyl-based polymer segment (a2) being bonded to the polysiloxane segment (a1) through a bond represented by the general formula (3). The bond represented by the general formula (3) is preferred because a sealing material to be obtained particularly has excellent acid resistance and alkali resistance.

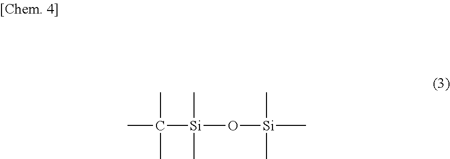

A silanol group and/or a hydrolyzable silyl group in the polysiloxane segment (a1) described below and a silanol group and/or a hydrolyzable silyl group in the vinyl-based polymer segment (a2) described below are bonded to each other through a dehydration-condensation reaction to form a bond represented by the general formula (3). Thus, in the general formula (3), a carbon atom constitutes a part of the vinyl-based polymer segment (a2) and a silicon atom bonded to only an oxygen atom constitutes a part of the polysiloxane segment (a1).

The composite resin (A) has, for example, a graft structure in which the polysiloxane segment (a1) is chemically bonded as a side chain of the polymer segment (a2) or a block structure in which the polymer segment (a2) and the polysiloxane segment (a1) are chemically bonded to each other.

(Polysiloxane Segment (a1))

The polysiloxane segment (a1) according to the present invention is a segment having a structural unit represented by general formula (1) and/or general formula (2) and a silanol group and/or a hydrolyzable silyl group. The structural unit represented by the general formula (1) and/or the general formula (2) contains a group having a polymerizable double bond.

(Structural Unit Represented by General Formula (1) and/or General Formula (2))

The structural unit represented by the general formula (1) and/or the general formula (2) contains a group having a polymerizable double bond as an essential component.

Specifically, R¹, R², and R³ in the general formulae (1) and (2) each independently represent a group having a polymerizable double bond selected from the group consisting of —R⁴—CH═CH₂, —R⁴—C(CH₃)═CH₂, —R⁴—O—CO—C(CH₃)═CH₂, and —R⁴—O—CO—CH═CH₂ (R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms, and at least one of R¹, R², and R³ represents the group having a polymerizable double bond. Examples of the alkylene group having 1 to 6 carbon atoms in R⁴ include a methylene group, an ethylene group, a propylene group, an isopropylene group, a butylene group, an isobutylene group, a sec-butylene group, a tert-butylene group, a pentylene group, an isopentylene group, a neopentylene group, a tert-pentylene group, a 1-methylbutylene group, a 2-methylbutylene group, a 1,2-dimethylpropylene group, a 1-ethylpropylene group, a hexylene group, an isohexylene group, a 1-methylpentylene group, a 2-methylpentylene group, a 3-methylpentylene group, a 1,1-dimethylbutylene group, a 1,2-dimethylbutylene group, a 2,2-dimethylbutylene group, a 1-ethylbutylene group, a 1,1,2-trimethylpropylene group, a 1,2,2-trimethylpropylene group, a 1-ethyl-2-methylpropylene group, and a 1-ethyl-1-methylpropylene group. In view of availability of a raw material, R⁴ is preferably a single bond or an alkylene group having 2 to 4 carbon atoms.

Examples of the alkyl group having 1 to 6 carbon atoms include a methyl group, an ethyl group, a propyl group, an isopropyl group, a butyl group, an isobutyl group, a sec-butyl group, a tert-butyl group, a pentyl group, an isopentyl group, a neopentyl group, a tert-pentyl group, a 1-methylbutyl group, a 2-methylbutyl group, a 1,2-dimethylpropyl group, a 1-ethylpropyl group, a hexyl group, an isohexyl group, a 1-methylpentyl group, a 2-methylpentyl group, a 3-methylpentyl group, a 1,1-dimethylbutyl group, a 1,2-dimethylbutyl group, a 2,2-dimethylbutyl group, a 1-ethylbutyl group, a 1,1,2-trimethylpropyl group, a 1,2,2-trimethylpropyl group, a 1-ethyl-2-methylpropyl group, and a 1-ethyl-1-methylpropyl group.

Examples of the cycloalkyl group having 3 to 8 carbon atoms include a cyclopropyl group, a cyclobutyl group, a cyclopentyl group, and a cyclohexyl group. Examples of the aryl group include a phenyl group, a naphthyl group, a 2-methylphenyl group, a 3-methylphenyl group, a 4-methylphenyl group, a 4-vinylphenyl group, and a 3-isopropylphenyl group.

Examples of the aralkyl group having 7 to 12 carbon atoms include a benzyl group, a diphenylmethyl group, and a naphthylmethyl group.

The specific meaning in which at least one of R¹, R², and R³ is the group having a polymerizable double bond is as follows. When the polysiloxane segment (a1) has only the structural unit represented by the general formula (1), R¹ is the group having a polymerizable double bond. When the polysiloxane segment (a1) has only the structural unit represented by the general formula (2), R² and/or R³ is the group having a polymerizable double bond. When the polysiloxane segment (a1) has both the structural units represented by the general formulae (1) and (2), at least one of R¹, R², and R³ is the group having a polymerizable double bond.

The structural unit represented by the general formula (1) and/or the general formula (2) is a three-dimensional network polysiloxane structural unit in which two or three bonding arms of a silicon atom are involved in crosslinking. Although a three-dimensional network structure is formed, a dense network structure is not formed. Therefore, gelation or the like is not caused during the production, and the long-term storage stability of a composite resin to be obtained is also improved.

(Silanol Group and/or Hydrolyzable Silyl Group)

In the present invention, the silanol group is a silicon-containing group having a hydroxyl group directly bonded to a silicon atom. Specifically, the silanol group is preferably a silanol group obtained by bonding a hydrogen atom to an oxygen atom having a bonding arm in the structural unit represented by the general formula (1) and/or the general formula (2).

In the present invention, the hydrolyzable silyl group is a silicon-containing group having a hydrolyzable group directly bonded to a silicon atom. An example of the hydrolyzable silyl group is a group represented by general formula (4).

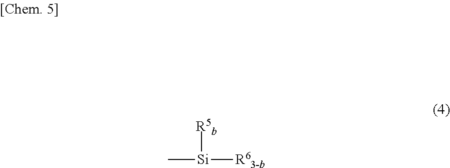

(In the general formula (4), R⁵ is a monovalent organic group such as an alkyl group, an aryl group, or an aralkyl group; R⁶ is a hydrolyzable group selected from the group consisting of a halogen atom, an alkoxy group, an acyloxy group, a phenoxy group, an aryloxy group, a mercapto group, an amino group, an amide group, an aminooxy group, an iminooxy group, and an alkenyloxy group; and b is an integer of 0 to 2.)

In R⁵, examples of the alkyl group include a methyl group, an ethyl group, a propyl group, an isopropyl group, a butyl group, an isobutyl group, a sec-butyl group, a tert-butyl group, a pentyl group, an isopentyl group, a neopentyl group, a tert-pentyl group, a 1-methylbutyl group, a 2-methylbutyl group, a 1,2-dimethylpropyl group, a 1-ethylpropyl group, a hexyl group, an isohexyl group, a 1-methylpentyl group, a 2-methylpentyl group, a 3-methylpentyl group, a 1,1-dimethylbutyl group, a 1,2-dimethylbutyl group, a 2,2-dimethylbutyl group, a 1-ethylbutyl group, a 1,1,2-trimethylpropyl group, a 1,2,2-trimethylpropyl group, a 1-ethyl-2-methylpropyl group, and a 1-ethyl-1-methylpropyl group.

Examples of the aryl group include a phenyl group, a naphthyl group, a 2-methylphenyl group, a 3-methylphenyl group, a 4-methylphenyl group, a 4-vinylphenyl group, and a 3-isopropylphenyl group.

Examples of the aralkyl group include a benzyl group, a diphenylmethyl group, and a naphthylmethyl group.

In R⁶, examples of the halogen atom include a fluorine atom, a chlorine atom, a bromine atom, and an iodine atom.

Examples of the alkoxy group include a methoxy group, an ethoxy group, a propoxy group, an isopropoxy group, a butoxy group, a sec-butoxy group, and a tert-butoxy group.

Examples of the acyloxy group include formyloxy, acetoxy, propanoyloxy, butanoyloxy, pivaloyloxy, pentanoyloxy, phenylacetoxy, acetoacetoxy, benzoyloxy, and naphthoyloxy.

Examples of the aryloxy group include phenyloxy and naphthyloxy.

Examples of the alkenyloxy group include a vinyloxy group, an allyloxy group, a 1-propenyloxy group, an isopropenyloxy group, a 2-butenyloxy group, a 3-butenyloxy group, a 2-pentenyloxy group, a 3-methyl-3-butenyloxy group, and a 2-hexenyloxy group.

When the hydrolyzable group represented by R⁶ is hydrolyzed, the hydrolyzable silyl group represented by the general formula (4) becomes a silanol group. A methoxy group or an ethoxy group is particularly preferred because of its high hydrolyzability.

Specifically, the hydrolyzable silyl group is preferably a hydrolyzable silyl group obtained by bonding/substituting the above-described hydrolyzable group to/for an oxygen atom having a bonding arm in the structural unit represented by the general formula (1) and/or the general formula (2).

In the silanol group and the hydrolyzable silyl group, when a cured product is formed using an active energy ray or heat, a hydrolysis condensation reaction between a hydroxyl group in the silanol group and the hydrolyzable group in the hydrolyzable silyl group proceeds together with a curing reaction. Therefore, the crosslinking density of a polysiloxane structure of a cured product to be obtained is increased, and thus the solvent resistance and the like can be improved.

The polysiloxane segment (a1) having the silanol group and the hydrolyzable silyl group and the vinyl-based polymer segment (a2) having an alcoholic hydroxyl group, which is described below, are bonded to each other through the bond represented by the general formula (3).

As long as the polysiloxane segment (a1) has the structural unit represented by the general formula (1) and/or the general formula (2) and the silanol group and/or the hydrolyzable silyl group, the polysiloxane segment (a1) is not particularly limited and may have other groups.

For example, there may be employed a polysiloxane segment (a1) having, in a combined manner, a structural unit in which R¹ in the general formula (1) is the group having a polymerizable double bond and a structural unit in which R¹ in the general formula (1) is an alkyl group such as methyl; a polysiloxane segment (a1) having, in a combined manner, a structural unit in which R¹ in the general formula (1) is the group having a polymerizable double bond, a structural unit in which R¹ in the general formula (1) is an alkyl group such as a methyl group, and a structural unit in which R² and R³ in the general formula (2) are each an alkyl group such as a methyl group; and a polysiloxane segment (a1) having, in a combined manner, a structural unit in which R¹ in the general formula (1) is the group having a polymerizable double bond and a structural unit in which R² and R³ in the general formula (2) are each an alkyl group such as a methyl group.

Specifically, the following structures are exemplified as a structure of the polysiloxane segment (a1).

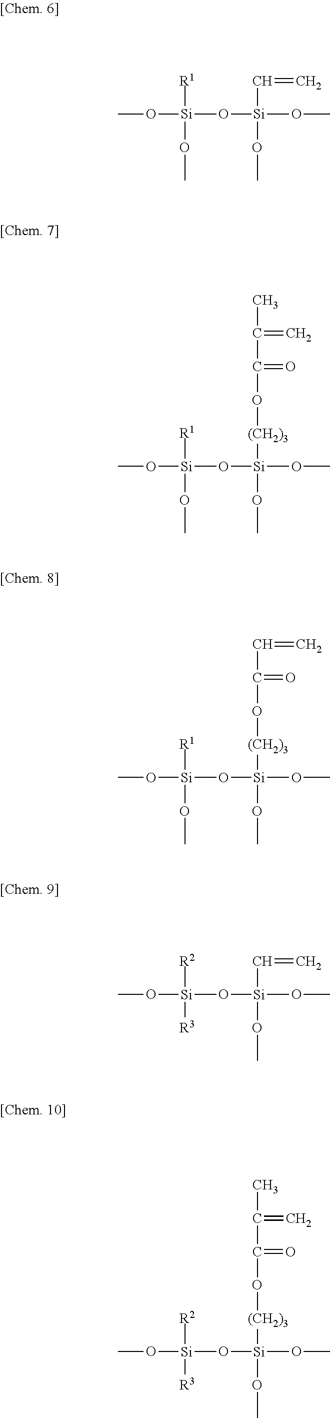

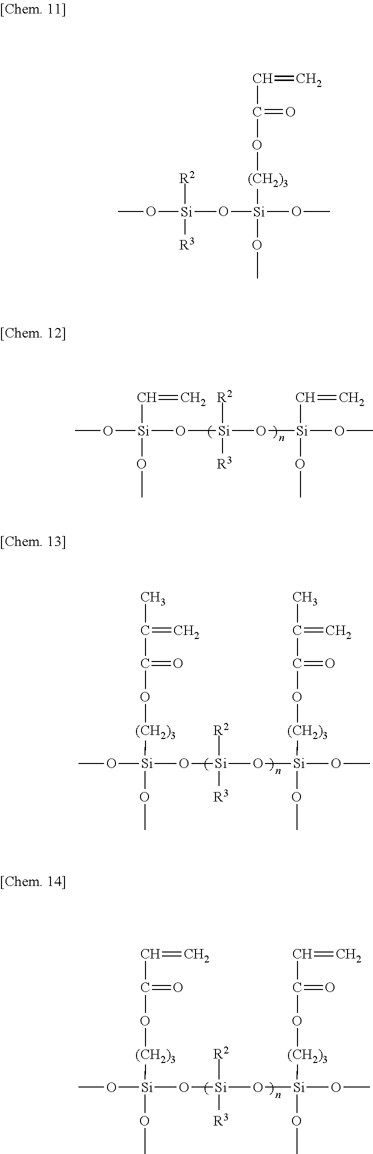

In the present invention, the content of the polysiloxane segment (a1) is 10% to 50% by weight relative to the total solid content of a curable resin composition, which can achieve both high weather resistance and high device-protecting performance. The content is preferably 15% to 40% by weight.

(Vinyl-Based Polymer Segment (a2) Having Alcoholic Hydroxyl Group)

The vinyl-based polymer segment (a2) according to the present invention is a vinyl polymer segment of an acrylic polymer, a fluoroolefin polymer, a vinyl ester polymer, an aromatic vinyl polymer, a polyolefin polymer, or the like, each of which has an alcoholic hydroxyl group. In particular, an acrylic-based polymer segment obtained by copolymerizing(meth)acrylic monomers having an alcoholic hydroxyl group is preferred because a resin cured product to be obtained has high transparency and gloss.

Examples of the (meth)acrylic monomers having an alcoholic hydroxyl group include 2-hydroxyethyl(meth)acrylate, 2-hydroxypropyl(meth)acrylate, 3-hydroxypropyl(meth)acrylate, 2-hydroxybutyl(meth)acrylate, 3-hydroxybutyl(meth)acrylate, 4-hydroxybutyl(meth)acrylate, 3-chloro-2-hydroxypropyl(meth)acrylate, di-2-hydroxyethyl fumarate, mono-2-hydroxyethylmonobutyl fumarate, polyethylene glycol mono(meth)acrylate, polypropylene glycol mono(meth)acrylate, various hydroxyalkyl esters of α,β-ethylenic unsaturated carboxylic acids such as “PLACCEL FM or PLACCEL FA” [caprolactone-addition monomer available from DAICEL CHEMICAL INDUSTRIES, LTD.], and addition products between ε-caprolactone and the foregoing.

In particular, 2-hydroxyethyl(meth)acrylate is preferred because the reaction is easily caused.

Since the content of the below-described polyisocyanate (B) is 5% to 50% by weight relative to the total solid content of a curable resin composition, the amount of the alcoholic hydroxyl group is preferably calculated and determined from the actual amount of the polyisocyanate (B) added.

In the present invention, as described below, an active energy ray-curable monomer having an alcoholic hydroxyl group is preferably used together. Therefore, the amount of the alcoholic hydroxyl group in the vinyl-based polymer segment (a2) having an alcoholic hydroxyl group can be determined by also taking into account the amount of the active energy ray-curable monomer having an alcoholic hydroxyl group. Practically, the amount of alcoholic hydroxyl group is preferably 30 to 300 in terms of the hydroxyl value of the vinyl-based polymer segment (a2).

Other (meth)acrylic monomers that can be copolymerized are not particularly limited, and publicly known monomers can be used. Vinyl monomers can also be copolymerized. Examples of the monomer include alkyl(meth)acrylates having an alkyl group with 1 to 22 carbon atoms, such as methyl(meth)acrylate, ethyl(meth)acrylate, n-propyl(meth)acrylate, n-butyl(meth)acrylate, isobutyl(meth)acrylate, tert-butyl(meth)acrylate, 2-ethylhexyl(meth)acrylate, and lauryl(meth)acrylate; aralkyl(meth)acrylates such as benzyl(meth)acrylate and 2-phenylethyl(meth)acrylate; cycloalkyl(meth)acrylates such as cyclohexyl(meth)acrylate and isobornyl(meth)acrylate; w-alkoxyalkyl(meth)acrylates such as 2-methoxyethyl(meth)acrylate and 4-methoxybutyl(meth)acrylate; aromatic vinyl-based monomers such as styrene, p-tert-butylstyrene, α-methylstyrene, and vinyltoluene; vinyl carboxylic acid esters such as vinyl acetate, vinyl propionate, vinyl pivalate, and vinyl benzoate; alkyl crotonic acid esters such as methyl crotonate and ethyl crotonate; dialkyl unsaturated dibasic acid esters such as dimethyl maleate, di-n-butyl maleate, dimethyl fumarate, and dimethyl itaconate; α-olefins such as ethylene and propylene; fluoroolefins such as vinylidene fluoride, tetrafluoroethylene, hexafluoropropylene, and chlorotrifluoroethylene; alkyl vinyl ethers such as ethyl vinyl ether and n-butyl vinyl ether; cycloalkyl vinyl ethers such as cyclopentyl vinyl ether and cyclohexyl vinyl ether; and monomers having a tertiary amide group, such as N,N-dimethyl(meth)acrylamide, N-(meth)acryloylmorpholine, N-(meth)acryloylpyrrolidine, and N-vinylpyrrolidone.

A polymerization method, a solvent, and a polymerization initiator used when the monomers are copolymerized are not particularly limited, and the vinyl-based polymer segment (a2) can be obtained by a publicly known method. For example, the vinyl-based polymer segment (a2) can be obtained by a polymerization method such as bulk radical polymerization, solution radical polymerization, or nonaqueous dispersion radical polymerization using a polymerization initiator such as 2,2′-azobis(isobutyronitrile), 2,2′-azobis(2,4-dimethylvaleronitrile), 2,2′-azobis(2-methylbutyronitrile), tert-butyl peroxypivalate, tert-butyl peroxybenzoate, tert-butyl peroxy-2-ethylhexanoate, di-tert-butyl peroxide, cumene hydroperoxide, or diisopropyl peroxycarbonate.

The number-average molecular weight (hereinafter abbreviated as Mn) of the vinyl-based polymer segment (a2) is preferably 500 to 200,000, which can prevent an increase in viscosity and gelation caused when the composite resin (A) is produced and provide high durability. Mn is more preferably 700 to 100,000 and further preferably 1,000 to 50,000.

In order to obtain the composite resin (A) including the vinyl-based polymer segment (a2) bonded to the polysiloxane segment (a1) through the bond represented by the general formula (3), the vinyl-based polymer segment (a2) has a silanol group and/or a hydrolyzable silyl group directly bonded to a carbon bond in the vinyl-based polymer segment (a2). The silanol group and/or the hydrolyzable silyl group are scarcely present in the vinyl-based polymer segment (a2) of the composite resin (A), which is an end product, because the bond represented by the general formula (3) is formed when the composite resin (A) described below is produced. However, there is no problem even if the silanol group and/or the hydrolyzable silyl group is left in the vinyl-based polymer segment (a2). When a resin cured product is formed using an active energy ray, a hydrolysis condensation reaction between a hydroxyl group in the silanol group and the hydrolyzable group in the hydrolyzable silyl group proceeds together with the curing reaction that uses an active energy ray. Therefore, the crosslinking density of a polysiloxane structure is increased, and thus a resin cured product having high solvent resistance and the like can be formed.

Specifically, the vinyl-based polymer segment (a2) having a silanol group and/or a hydrolyzable silyl group directly bonded to a carbon bond is obtained by copolymerizing the (meth)acrylic monomer having an alcoholic hydroxyl group, the above-described typical monomer, and a vinyl-based monomer having a silanol group and/or a hydrolyzable silyl group directly bonded to a carbon bond.

Examples of the vinyl-based monomer having a silanol group and/or a hydrolyzable silyl group directly bonded to a carbon bond include vinyltrimethoxysilane, vinyltriethoxysilane, vinylmethyldimethoxysilane, vinyltri(2-methoxyethoxy)silane, vinyltriacetoxysilane, vinyltrichlorosilane, 2-trimethoxysilylethyl vinyl ether, 3-(meth)acryloyloxypropyltrimethoxysilane, 3-(meth)acryloyloxypropyltriethoxysilane, 3-(meth)acryloyloxypropylmethyldimethoxysilane, and 3-(meth)acryloyloxypropyltrichlorosilane. In particular, vinyltrimethoxysilane and 3-(meth)acryloyloxypropyltrimethoxysilane are preferred because a hydrolysis reaction can be easily caused to proceed and by-products after the reaction can be easily removed.

### (Method for Producing Composite Resin (A))

The composite resin (A) used in the present invention is specifically produced by (method 1), (method 2), or (method 3) below.

### (Method 1)

The (meth)acrylic monomer having an alcoholic hydroxyl group, the above-described typical (meth)acrylic monomer, and the vinyl-based monomer having a silanol group and/or a hydrolyzable silyl group directly bonded to a carbon bond are copolymerized to obtain a vinyl-based polymer segment (a2) having a silanol group and/or a hydrolyzable silyl group directly bonded to a carbon bond. The vinyl-based polymer segment (a2) is mixed with a silane compound having both a silanol group and/or a hydrolyzable silyl group and a polymerizable double bond and optionally with a typical silane compound to induce a hydrolysis condensation reaction.

In this method, a hydrolysis condensation reaction is induced between a silanol group or a hydrolyzable silyl group of the silane compound having both a silanol group and/or a hydrolyzable silyl group and a polymerizable double bond and a silanol group and/or a hydrolyzable silyl group of the vinyl-based polymer segment (a2) having a silanol group and/or a hydrolyzable silyl group directly bonded to a carbon bond. As a result, the polysiloxane segment (a1) is formed while at the same time the composite resin (A) is obtained by bonding the polysiloxane segment (a1) and the vinyl-based polymer segment (a2) having an alcoholic hydroxyl group to each other through the bond represented by the general formula (3).

### [Method 2]

In the same manner as in the method 1, a vinyl-based polymer segment (a2) having a silanol group and/or a hydrolyzable silyl group directly bonded to a carbon bond is obtained.

A hydrolysis condensation reaction is induced on a silane compound having both a silanol group and/or a hydrolyzable silyl group and a polymerizable double bond and optionally a typical silane compound to obtain a polysiloxane segment (a1). Subsequently, a hydrolysis condensation reaction is induced between a silanol group and/or a hydrolyzable silyl group of the vinyl-based polymer segment (a2) and a silanol group and/or a hydrolyzable silyl group of the polysiloxane segment (a1).

### (Method 3)

In the same manner as in the method 1, a vinyl-based polymer segment (a2) having a silanol group and/or a hydrolyzable silyl group directly bonded to a carbon bond is obtained. In the same manner as in the method 2, a polysiloxane segment (a1) is obtained. Furthermore, a silane compound containing a silane compound having a polymerizable double bond and optionally a typical silane compound are mixed therein to induce a hydrolysis condensation reaction.

Examples of the silane compound having both a silanol group and/or a hydrolyzable silyl group and a polymerizable double bond, the silane compound being used in the (method 1) to (method 3), include vinyltrimethoxysilane, vinyltriethoxysilane, vinylmethyldimethoxysilane, vinyltri(2-methoxyethoxy)silane, vinyltriacetoxysilane, vinyltrichlorosilane, 2-trimethoxysilylethyl vinyl ether, 3-(meth)acryloyloxypropyltrimethoxysilane, 3-(meth)acryloyloxypropyltriethoxysilane, 3-(meth)acryloyloxypropylmethyldimethoxysilane, and 3-(meth)acryloyloxypropyltrichlorosilane. In particular, vinyltrimethoxysilane and 3-(meth)acryloyloxypropyltrimethoxysilane are preferred because a hydrolysis reaction can be easily caused to proceed and by-products after the reaction can be easily removed.

In addition, examples of the typical silane compound used in the (method 1) to (method 3) include various organotrialkoxysilanes such as methyltrimethoxysilane, methyltriethoxysilane, methyltri-n-butoxysilane, ethyltrimethoxysilane, n-propyltrimethoxysilane, isobutyltrimethoxysilane, cyclohexyltrimethoxysilane, phenyltrimethoxysilane, and phenyltriethoxysilane; various diorganodialkoxysilanes such as dimethyldimethoxysilane, dimethyldiethoxysilane, dimethyldi-n-butoxysilane, diethyldimethoxysilane, diphenyldimethoxysilane, methylcyclohexyldimethoxysilane, and methylphenyldimethoxysilane; and chlorosilanes such as methyltrichlorosilane, ethyltrichlorosilane, phenyltrichlorosilane, vinyltrichlorosilane, dimethyldichlorosilane, diethyldichlorosilane, and diphenyldichlorosilane. In particular, organotrialkoxysilanes and diorganodialkoxysilanes are preferred because a hydrolysis reaction can be easily caused to proceed and by-products after the reaction can be easily removed.

A tetrafunctional alkoxysilane compound such as tetramethoxysilane, tetraethoxysilane, or tetra-n-propoxysilane or a partial hydrolysis condensate of the tetrafunctional alkoxysilane compound can be used together as long as the advantages of the present invention are not impaired. When the tetrafunctional alkoxysilane compound or the partial hydrolysis condensate thereof is used together, the ratio of silicon atoms contained in the tetrafunctional alkoxysilane compound relative to all silicon atoms that constitute the polysiloxane segment (a1) is preferably 20 mol % or less.

A metal alkoxide compound with a metal other than silicon, such as boron, titanium, zirconium, or aluminum, can be used together with the silane compound above as long as the advantages of the present invention are not impaired. For example, the ratio of metal atoms contained in the metal alkoxide compound relative to all silicon atoms that constitute the polysiloxane segment (a1) is preferably 25 mol % or less.

In the hydrolysis condensation reaction in the (method 1) to (method 3), part of the hydrolyzable group is hydrolyzed due to the effect of water or the like to form a hydroxyl group and then a condensation reaction proceeds between the hydroxyl groups or between the hydroxyl group and a hydrolyzable group. The hydrolysis condensation reaction can be caused to proceed by a publicly known method, and a method for causing the reaction to proceed by supplying water and a catalyst in the above-described production process is convenient and preferred.

Examples of the catalyst used include inorganic acids such as hydrochloric acid, sulfuric acid, and phosphoric acid; organic acids such as p-toluenesulfonic acid, monoisopropyl phosphoric acid, and acetic acid; inorganic bases such as sodium hydroxide and potassium hydroxide; titanic acid esters such as tetraisopropyl titanate and tetrabutyl titanate; various compounds containing basic nitrogen atoms such as 1,8-diazabicyclo[5.4.0]undecene-7 (DBU), 1,5-diazabicyclo[4.3.0]nonene-5 (DBN), 1,4-diazabicyclo[2.2.2]octane (DABCO), tri-n-butylamine, dimethylbenzylamine, monoethanolamine, imidazole, and 1-methylimidazole; various quaternary ammonium salts having chloride, bromide, carboxylate, hydroxide, or the like as a counteranion, such as tetramethylammonium salts, tetrabutylammonium salts, and dilauryldimethylammonium salts; and tin carboxylates such as dibutyltin diacetate, dibutyltin dioctoate, dibutyltin dilaurate, dibutyltin diacetylacetonate, tin octylate, and tin stearate. These catalysts may be used alone or in combination of two or more.

The amount of the catalyst added is not particularly limited, and is preferably 0.0001% to 10% by weight, more preferably 0.0005% to 3% by weight, and particularly preferably 0.001% to 1% by weight relative to the total amount of the compounds each having a silanol group or a hydrolyzable silyl group.

The amount of water supplied is preferably 0.05 mol or more, more preferably 0.1 mol or more, and particularly preferably 0.5 mol or more relative to 1 mol of a silanol group or a hydrolyzable silyl group of the compounds each having a silanol group or a hydrolyzable silyl group.

The catalyst and water may be collectively or consecutively supplied or a mixture of the catalyst and water may be supplied.

The reaction temperature of the hydrolysis condensation reaction in the (method 1) to (method 3) is suitably 0° C. to 150° C. and preferably 20° C. to 100° C. The reaction can be caused under normal pressure, increased pressure, or reduced pressure. An alcohol and water, which are by-products of the hydrolysis condensation reaction, may be removed by a method such as distillation, if required.

The ratio of compounds prepared in the (method 1) to (method 3) is suitably selected in accordance with the desired structure of the composite resin (A) used in the present invention. To achieve high durability of a film obtained, the composite resin (A) is obtained so that the content of the polysiloxane segment (a1) is preferably 30% to 80% by weight and more preferably 30% to 75% by weight.

In the (method 1) to (method 3), the polysiloxane segment and the vinyl-based polymer segment are combined with each other in a block manner by the following method. A vinyl-based polymer segment having a structure in which the silanol group and/or the hydrolyzable silyl group is present at only one terminal or both terminals of a polymer chain is used as an intermediate. For example, in the case of the (method 1), a silane compound having both a silanol group and/or a hydrolyzable silyl group and a polymerizable double bond and optionally a typical silane compound are added to the vinyl-based polymer segment to induce a hydrolysis condensation reaction.

In the (method 1) to (method 3), the vinyl-based polymer segment is combined with the polysiloxane segment in a graft manner by the following method. A vinyl-based polymer segment having a structure in which the silanol group and/or the hydrolyzable silyl group is randomly distributed to the main chain of the vinyl-based polymer segment is used as an intermediate. For example, in the case of the (method 2), a hydrolysis condensation reaction is induced between a silanol group and/or a hydrolyzable silyl group of the vinyl-based polymer segment and a silanol group and/or a hydrolyzable silyl group of the polysiloxane segment.

### (Polyisocyanate (B))

A sealing material of the present invention contains a polyisocyanate (B) in an amount of 5% to 50% by weight relative to the total solid content of a curable resin composition.

By setting the content of polyisocyanate in the above range, long-term weather resistance, particularly crack resistance, in the open air is improved. Furthermore, even if a stress that causes a change in size due to thermal expansion and shrinkage is exerted in a thermal cycle test of a device or in a practical thermal cycle environment, the shape can be maintained.

This may be because a polyisocyanate and a hydroxyl group in the system (a hydroxyl group in the vinyl-based polymer segment (a2) or a hydroxyl group in the below-described active energy ray-curable monomer having an alcoholic hydroxyl group) react with each other and consequently a urethane bond, which is a soft segment, is formed, and thus the urethane bond reduces the concentration of stress caused by curing derived from polymerizable double bonds.

If the content of the polyisocyanate (B) is less than 5% by weight relative to the total solid content of a curable resin composition, cracks are generated on a resin cured product obtained from the composition after long-term exposure in the open air. If the content of the polyisocyanate (B) is more than 50% by weight relative to the total solid content of a curable resin composition, the curing property of the composition degrades. In a worse case, tackiness may be left on the surface.

The polyisocyanate (B) used is not particularly limited, and a publicly known polyisocyanate can be used. However, a polyisocyanate mainly composed of an aromatic diisocyanate such as tolylenediisocyanate or diphenylmethane-4,4′-diisocyanate or an aralkyl diisocyanate such as m-xylylene diisocyanate or α,α,α′,α′-tetramethyl-m-xylylene diisocyanate is preferably used in the minimum amount because such a polyisocyanate has a problem in terms of light resistance in that a sealing material turns yellow after long-term outdoor exposure.

From the viewpoint of long-term use in the open air, an aliphatic polyisocyanate mainly composed of an aliphatic diisocyanate is suitable as the polyisocyanate used in the present invention. Examples of the aliphatic diisocyanate include tetramethylene diisocyanate, 1,5-pentamethylene diisocyanate, 1,6-hexamethylene diisocyanate (hereinafter abbreviated as “HDI”), 2,2,4- or 2,4,4-trimethyl-1,6-hexamethylene diisocyanate, lysine isocyanate, isophorone diisocyanate, hydrogenated xylene diisocyanate, hydrogenated diphenylmethane diisocyanate, 1,4-diisocyanatocyclohexane, 1,3-bis(diisocyanatomethyl)cyclohexane, and 4,4′-dicyclohexylmethane diisocyanate. Among them, HDI is particularly suitable in terms of crack resistance and cost.

Examples of the aliphatic polyisocyanate obtained from the aliphatic diisocyanate include allophanate-type polyisocyanate, biuret-type polyisocyanate, adduct-type polyisocyanate, and isocyanurate-type polyisocyanate, all of which can be suitably used.

A so-called block polyisocyanate compound obtained so as to have a block structure using various blocking agents can also be used as the above-described polyisocyanate. Examples of the blocking agents include alcohols such as methanol, ethanol, and lactic acid ester; phenolic compounds having a hydroxyl group such as phenol and salicylic acid ester; amides such as ε-caprolactam and 2-pyrrolidone; oximes such as acetone oxime and methyl ethyl ketoxime; and active methylene compounds such as methyl acetoacetate, ethyl acetoacetate, and acetylacetone.

The ratio of the isocyanate group in the polyisocyanate (B) is preferably 3% to 30% by weight relative to the total solid content of the polyisocyanate in terms of the crack resistance and weather resistance of a resin cured product. If the ratio of the isocyanate group in the polyisocyanate (B) is less than 3%, the reactivity of polyisocyanate is low. If the ratio is more than 30%, the molecular weight of polyisocyanate is decreased. In either case, caution is required because stress relaxation is not achieved.

The polyisocyanate and a hydroxyl group in the system (a hydroxyl group in the vinyl-based polymer segment (a2) or a hydroxyl group in the below-described active energy ray-curable monomer having an alcoholic hydroxyl group) react with each other without heating or the like. In the case where the curing process is performed using UV, after coating and irradiation with UV are performed, the reaction gradually proceeds at room temperature. If necessary, after the irradiation with UV, heating at 80° C. may be performed for several minutes to several hours (20 minutes to 4 hours) to facilitate the reaction between the alcoholic hydroxyl group and the isocyanate. In this case, a publicly known urethane-forming catalyst may be optionally used. The urethane-forming catalyst is suitably selected in accordance with the desired reaction temperature.

### (Sealing Material)

The sealing material of the present invention has a polymerizable double bond as described above, and thus can be cured with heat, an active energy ray such as ultraviolet rays, or heat and an active energy ray. Hereinafter, the case where the sealing material is cured with heat and the case where the sealing material is cured with ultraviolet rays will be described.

When the sealing material of the present invention is cured with ultraviolet rays, a photopolymerization initiator is preferably used. A publicly known photopolymerization initiator may be used, and at least one selected from the group consisting of acetophenones, benzylketals, and benzophenones can be preferably used. Examples of the acetophenones include diethoxyacetophenone, 2-hydroxy-2-methyl-1-phenylpropan-1-on, 1-(4-isopropylphenyl)-2-hydroxy-2-methylpropan-1-on, and 4-(2-hydroxyethoxy)phenyl-(2-hydroxy-2-propyl)ketone. Examples of the benzylketals include 1-hydroxycyclohexyl phenyl ketone and benzyldimethylketal. Examples of the benzophenones include benzophenone and methyl o-benzoylbenzoate. Examples of the benzoins include benzoin, benzoin methyl ether, and benzoin isopropyl ether. The photopolymerization initiators (B) may be used alone or in combination of two or more.

The amount of the photopolymerization initiator (B) used is preferably 1% to 15% by weight and more preferably 2% to 10% by weight relative to 100% by weight of the composite resin (A).

When the sealing material is cured with ultraviolet rays, preferably, a multifunctional (meth)acrylate is optionally contained. Since a multifunctional (meth)acrylate is caused to react with the polyisocyanate (B) as described above, the multifunctional (meth)acrylate preferably has an alcoholic hydroxyl group. Examples of the multifunctional (meth)acrylate include multifunctional (meth)acrylates having two or more polymerizable double bonds in a single molecule, such as 1,2-ethanediol diacrylate, 1,2-propanediol diacrylate, 1,4-butanediol diacrylate, 1,6-hexanediol diacrylate, dipropylene glycol diacrylate, neopentyl glycol diacrylate, tripropylene glycol diacrylate, trimethylolpropane diacrylate, trimethylolpropane triacrylate, tris(2-acryloyloxy) isocyanurate, pentaerythritol triacrylate, pentaerythritol tetraacrylate, di(trimethylolpropane)tetraacrylate, di(pentaerythritol)pentaacrylate, and di(pentaerythritol) hexaacrylate. In addition, a urethane acrylate, a polyester acrylate, an epoxy acrylate, and the like can be exemplified as the multifunctional acrylate. They may be used alone or in combination of two or more.

In particular, pentaerythritol triacrylate and di(pentaerythritol)pentaacrylate are preferred in terms of hardness of a resin cured product and stress relaxation in a reaction with a polyisocyanate.

A monofunctional (meth)acrylate can also be used together with the multifunctional (meth)acrylate. Examples of the monofunctional (meth)acrylate include (meth)acrylic acid esters having a hydroxyl group, such as hydroxyethyl(meth)acrylate, hydroxypropyl(meth)acrylate, hydroxybutyl(meth)acrylate, caprolactone-modified hydroxy(meth)acrylate (e.g., product name “PLACCEL” available from DAICEL CHEMICAL INDUSTRIES, LTD.), mono(meth)acrylate of polyester diol obtained from phthalic acid and propylene glycol, mono(meth)acrylate of polyester diol obtained from succinic acid and propylene glycol, polyethylene glycol mono(meth)acrylate, polypropylene glycol mono(meth)acrylate, pentaerythritol tri(meth)acrylate, 2-hydroxy-3-(meth)acryloyloxypropyl(meth)acrylate, and various (meth)acrylic acid adducts of epoxy esters; vinyl monomers having a carboxyl group, such as (meth)acrylic acid, crotonic acid, itaconic acid, maleic acid, and fumaric acid; vinyl monomers having a sulfonic acid group, such as vinylsulfonic acid, styrenesulfonic acid, and sulfoethyl(meth)acrylate; acid phosphate-based vinyl monomers such as 2-(meth)acryloyloxyethyl acid phosphate, 2-(meth)acryloyloxypropyl acid phosphate, 2-(meth)acryloyloxy-3-chloropropyl acid phosphate, and 2-methacryloyloxyethylphenylphosphoric acid; and vinyl monomers having a methylol group such as N-methylol(meth)acrylamide. They can be used alone or in combination of two or more. In consideration of the reactivity with an isocyanate group of the multifunctional isocyanate (b), a (meth)acrylic acid ester having a hydroxyl group is particularly preferred as a monomer (c).

The amount of the multifunctional (meth)acrylate (C) used is preferably 1% to 85% by weight and more preferably 5% to 80% by weight relative to the total solid content of the sealing material of the present invention. By using the multifunctional acrylate within the range, for example, the hardness of a resin cured product to be obtained can be improved.

### (Active Energy Ray)

Examples of the active energy ray used when the sealing material of the present invention is cured with an active energy ray include electron beams, ultraviolet rays, and infrared rays. Among them, ultraviolet rays are preferred because of their convenience. Light used in the ultraviolet curing can be emitted from, for example, a low-pressure mercury lamp, a high-pressure mercury lamp, a metal halide lamp, a xenon lamp, an argon laser, or a helium-cadmium laser. Using such a lamp or laser, a curable resin composition is irradiated with ultraviolet rays having a wavelength of about 180 to 400 nm, whereby the curable resin composition can be cured. The ultraviolet radiation dose is suitably selected in accordance with the type and amount of a photopolymerization initiator used.

Light used in the ultraviolet curing can be emitted from, for example, a low-pressure mercury lamp, a high-pressure mercury lamp, a metal halide lamp, a xenon lamp, an argon laser, or a helium-cadmium laser. Using such a lamp or laser, a surface coated with a ultraviolet-curable resin composition is irradiated with ultraviolet rays having a wavelength of about 180 to 400 nm, whereby the ultraviolet-curable resin composition can be cured. The ultraviolet radiation dose is suitably selected in accordance with the type and amount of a photopolymerization initiator used.

When the sealing material of the present invention is cured with heat, in consideration of the reaction temperature and reaction time of a reaction of polymerizable double bonds and a urethane-forming reaction between an alcoholic hydroxyl group and an isocyanate in the composition, catalysts for the reactions are preferably selected. A thermosetting resin can also be used together. Examples of the thermosetting resin include vinyl-based resin, unsaturated polyester resin, polyurethane resin, epoxy resin, epoxy ester resin, acrylic resin, phenolic resin, petroleum resin, ketone resin, and silicon resin and modified resins of the foregoing.

Furthermore, various additives such as an inorganic pigment, an organic pigment, an extender, a clay mineral, a wax, a surfactant, a stabilizer, a fluidity adjusting agent, a dye, a leveling agent, a rheology controlling agent, an ultraviolet absorber, an antioxidant, and a plasticizer can be optionally used in the sealing material of the present invention as long as the transparency can be ensured.

The composite resin (A) contained in the sealing material of the present invention has a polysiloxane segment (a1) and a vinyl-based polymer segment (a2), and thus the sealing material is relatively compatible with an acrylic resin and an active energy ray-curable monomer. Therefore, a composition having high compatibility can be obtained.

### (Sealing Material for Light-Emitting Diode)

When the sealing material of the present invention is used as a sealing material for light-emitting diodes, a phosphor may be added to the sealing material. The phosphor absorbs light emitted from a light-emitting element and converts the wavelength of the light, and thus a light-emitting diode having a color tone different from a color tone of the light-emitting element can be provided. A phosphor used in light-emitting diodes is at least one phosphor selected from a phosphor that emits blue light, a phosphor that emits green light, a phosphor that emits yellow light, and a phosphor that emits red light. Such a phosphor is added to the sealing material for light-emitting diodes according to the present invention and mixed until the phosphor is substantially uniformly dispersed. The mixture is placed on a peripheral portion of the light-emitting element. The phosphor absorbs light emitted from the light-emitting element, converts the wavelength of the light, and emits light having a wavelength different from that of the light emitted from the light-emitting element. Thus, part of the light emitted from the light-emitting element and part of the light emitted from the phosphor are mixed with each other, and a multicolor light-emitting diode including a white light-emitting diode can be produced.

Inorganic fine particles of glass, alumina, aluminum hydroxide, fused silica, crystalline silica, ultra-fine amorphous silica or ultra-fine hydrophobic silica, talc, clay, barium sulfate, and the like may be added in order to reduce the shrinkage on the curing of a composition, thereby achieving the precise shape and size of cracks and components as designed, and in order to improve the heat resistance and thermal conductivity.

Since the sealing material of the present invention has high resistance to light, particularly light having a short wavelength, the sealing material can be used as a sealing material for various light-emitting diodes such as a red light-emitting diode, a green light-emitting diode, and a blue light-emitting diode. In particular, the sealing material of the present invention has excellent functions as a sealing material for a white light-emitting diode that needs to have higher resistance to light having a short wavelength.

The sealing material of the present invention has not only high light resistance but also high heat resistance and high wet heat resistance. Therefore, the sealing material can be suitably used in the open air in which temperature and humidity change significantly.

When a light-emitting diode is produced using the sealing material of the present invention, a publicly known method may be employed. For example, a light-emitting diode can be produced by coating a light-emitting element with the sealing material for light-emitting diodes according to the present invention.

The light-emitting element is not particularly limited, and any light-emitting element that can be used for light-emitting diodes can be used. An example of the light-emitting element is a light-emitting element produced by stacking a semiconductor material such as a nitride compound semiconductor on a sapphire substrate.

The emission wavelength of the light-emitting element is not particularly limited in an ultraviolet region to an infrared region, but the advantages of the present invention are significantly produced when a light-emitting element having a main emission peak wavelength of 550 nm or less is used. A single light-emitting element may be used to emit monochromatic light. A plurality of light-emitting elements may be used to emit monochromatic light or polychromatic light.

The term “coating” above means not only the case where the light-emitting element is directly sealed but also the case where the light-emitting element is indirectly coated. Specifically, the light-emitting element may be directly sealed using the sealing material of the present invention by a publicly known method. The light-emitting element is sealed with glass or sealing resin such as epoxy resin, silicone resin, acrylic resin, urea resin, or imide resin, and then the glass or sealing resin or a peripheral portion of the glass or sealing resin may be coated with the sealing material of the present invention. Alternatively, the light-emitting element is sealed with the sealing material of the present invention, and then the sealing material may be molded (also called “sealed”) with epoxy resin, silicone resin, acrylic resin, urea resin, or imide resin. By employing such a method, various effects such as a lens effect can be produced using the difference in refractive index or specific gravity.

Various methods can be employed as a sealing method. For example, using a dispenser or another method, a liquid sealing material may be injected into, for example, a cup, a cavity, or a depressed portion of a package in which a light-emitting element is disposed on the bottom, and then the liquid sealing material may be cured by performing heating or the like. Alternatively, a solid sealing material or a high viscosity liquid sealing material may be fluidized by performing heating or the like, injected into, for example, a depressed portion of a package, and then cured by performing heating or the like. The package can be composed of a material such as polycarbonate resin, polyphenylenesulfide resin, epoxy resin, acrylic resin, silicone resin, ABS resin, polybutylene terephthalate resin, or polyphthalamide resin. Furthermore, a lead frame including a light-emitting element fixed thereon may be immersed in a sealing material that has been injected into a mold in advance and then the sealing material may be cured. Alternatively, a sealing material is injected, using a dispenser, into a mold into which a light-emitting element has been inserted, and then transfer molding, injection molding, or the like may be performed to mold and cure a sealing layer composed of the sealing material. A liquid or fluidized sealing material may be simply dropped on a light-emitting element or a light-emitting element may be coated with such a sealing material, and then the sealing material may be cured. A sealing material can also be molded and cured by applying the sealing material onto a light-emitting element by mimeograph printing or screen printing or with a mask. A sealing material that has been partly or completely cured in a plate-like shape or a lens-like shape may be disposed on a light-emitting element. In addition, the sealing material can be used as a die bonding material for fixing a light-emitting element on a lead terminal or a package. The sealing material can also be used as a passivation film on a light-emitting element. The sealing material can also be used as a package substrate.

The shape of the light-emitting diode to which the sealing material is applied is not particularly limited, and can be suitably selected in accordance with the use of the light-emitting diode. Specifically, shell-type light-emitting diodes and surface mount-type light-emitting diodes, which are employed in illumination devices, are exemplified.

### (Sealing Material for Solar Cell)

When the sealing material of the present invention is used as a sealing material for solar cells, there is no particular limitation. A liquid sealing material may be used by being applied onto a solar cell composed of a monocrystalline or polycrystalline silicon cell (crystalline silicon cell), amorphous silicon, a compound semiconductor (thin film cell), or the like. Alternatively, a solar cell may be sandwiched between sealing materials formed into a sheet-like shape, and the sealing materials formed into a sheet-like shape may be coated with glass or a back sheet. Then, a heat treatment may be performed to melt the sealing materials formed into a sheet-like shape and consequently the entire object is sealed in an integrated manner (modularized). In particular, the sealing material formed into a sheet-like shape (hereinafter referred to as sealing sheet) is preferred because a modularization step is easily performed and thus a solar cell module can be stably supplied.

The sealing material of the present invention can be formed into a sheet-like shape by a publicly known method. For example, a resin is melted in an extruding machine, and the melted resin is extruded from a die and rapidly cooled and solidified to obtain an original film. A T die, a ring die, or the like is used as the extruding machine. When the resin sealing sheet has a multilayer structure, a ring die is preferably used.

Embossing may be performed on the surface of the original film in accordance with the application of the resin sealing sheet. When embossing is performed on both surfaces, the original film is passed between two heated embossing rolls. When embossing is performed on one surface, the original film is passed between two embossing rolls, only one of which is heated.

When a multilayer structure is formed, a multilayer T die method, a multilayer circular die method, or the like can be selected. A multilayer structure may also be formed by a publicly known method such as a laminating method.

The sealing sheet is preferably in a gel state which is provided by partly causing a urethane-forming reaction between an alcoholic hydroxyl group and an isocyanate in advance. Specifically, the sealing sheet is preferably cured for several hours at about 40° C. to 100° C. at which a urethane-forming reaction proceeds.

Any aftertreatment may be optionally performed. Examples of the aftertreatment include heat setting that provides dimensional stability, corona treatment, plasma treatment, and lamination with other resin sealing sheets.

### (Solar Cell Module)

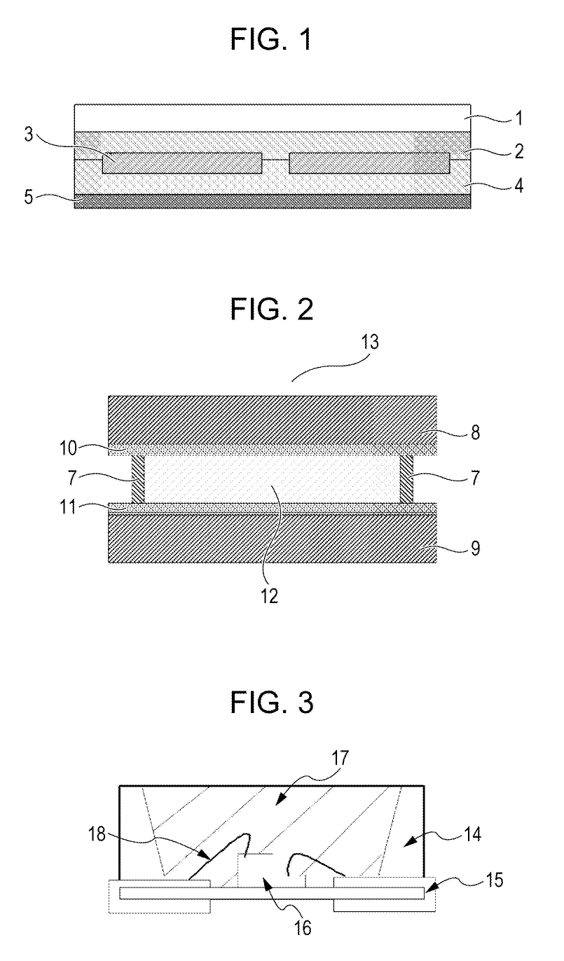

FIG. 1 shows an example of a specific embodiment of a solar cell module that uses the sealing sheet for solar cells obtained by the above-described method. Note that the present invention obviously includes various embodiments that are not described herein.

The solar cell module shown in FIG. 1 is obtained by sequentially stacking a light-receiving-side protective sheet 1 for solar cells, a first sealing material 2, a group of cells 3, a second sealing material 4, and a protective sheet 5 for solar cells.

The first sealing material 2 and the second sealing material 4 are disposed between the light-receiving-side protective sheet 1 for solar cells and the protective sheet 5 for cells to seal the group of solar cells 3.

Therefore, by heating the first sealing material 2 and the second sealing material 4 to a certain crosslinking temperature or higher, they are softened and then crosslinking is initiated.

A method for producing a solar cell module by performing sealing is not particularly limited. Specifically, using a vacuum laminator, materials such as sealing materials and solar cells are stacked in a mold and then vacuum pressing is performed to produce a solar cell.

As described above, the group of solar cells 3 includes a plurality of solar cells composed of a monocrystalline or polycrystalline silicon cell (crystalline silicon cell), amorphous silicon, a compound semiconductor (thin film cell), or the like and a wire. The plurality of solar cells are electrically connected to each other through the wire.

After that, the first sealing material 2 and the second sealing material 4 laminated using a laminating machine are fully cured by performing heating, whereby a solar cell module can be obtained.

### EXAMPLES

The present invention will now be specifically described based on Examples and Comparative Examples. In Examples, “part” and “%” are on a weight basis unless otherwise specified.

### Synthesis Example 1

### Preparation Example of Polysiloxane (a1-1)

There were prepared 415 parts of methyltrimethoxysilane (MTMS) and 756 parts of 3-methacryloyloxypropyltrimethoxysilane (MPTS) in a reactor including a stirrer, a thermometer, a dropping funnel, a cooling tube, and a nitrogen gas inlet. They were heated to 60° C. while being stirred under the ventilation of nitrogen gas. Subsequently, a mixture of 0.1 parts of “A-3” [isopropyl acid phosphate available from Sakai Chemical Industry Co., Ltd.] and 121 parts of deionized water was added dropwise thereto for five minutes. After the dropwise addition, the temperature in the reactor was increased to 80° C. and stirring was performed for four hours to induce a hydrolysis condensation reaction. Thus, a reaction product was obtained.

Methanol and water contained in the obtained reaction product were removed at 40° C. to 60° C. at a reduced pressure of 1 to 30 kilopascals (kPa) to obtain 1000 parts of polysiloxane (a1-1) having a number-average molecular weight of 1000 and an effective content of 75.0%.

Herein, the “effective content” is a value calculated by dividing the theoretical yield (parts by weight) in the case where all methoxy groups of a silane monomer used are subjected to a hydrolysis condensation reaction by the actual yield (parts by weight) after the hydrolysis condensation reaction. In other words, the “effective content” is calculated from the formula of [theoretical yield (parts by weight) in the case where all methoxy groups of a silane monomer are subjected to a hydrolysis condensation reaction/actual yield (parts by weight) after the hydrolysis condensation reaction].

### Synthesis Example 2

### Preparation Example of Vinyl-Based Polymer (a2-1)

There were prepared 20.1 parts of phenyltrimethoxysilane (PTMS), 24.4 parts of dimethyldimethoxysilane (DMDMS), and 44.7 parts of isopropanol in the same reactor as that of Synthesis Example 1. They were heated to 80° C. while being stirred under the ventilation of nitrogen gas. Subsequently, a mixture of 67.0 parts of n-butyl methacrylate (BMA), 97.5 parts of 2-ethylhexyl methacrylate (EHMA), 83 parts of butyl acrylate, 3.8 parts of acrylic acid (AA), 11.25 parts of MPTS, 112.5 parts of 2-hydroxyethyl methacrylate (HEMA), and 56.3 parts of tert-butylperoxy-2-ethylhexanoate (TBPEH) was added dropwise to the reactor for four hours while being stirred at the same temperature under the ventilation of nitrogen gas. After stirring was further performed at that temperature for two hours, a mixture of 0.05 parts of “A-3” and 12.8 parts of deionized water was added dropwise to the reactor for five minutes, and stirring was performed at that temperature for four hours to induce a hydrolysis condensation reaction of PTMS, DMDMS, and MPTS to proceed. A ¹H-NMR analysis of the reaction product found that almost 100% of the trimethoxysilyl group of the silane monomer in the reactor was hydrolyzed. Next, by performing stirring at that temperature for ten hours, a vinyl-based polymer (a2-1) which was a reaction product having a residual amount of TBPEH of 0.1% or less was obtained.

### Synthesis Example 3

### Preparation Example of Composite Resin (A-1)

To 345.7 parts of the vinyl-based polymer (a2-1) prepared in Synthesis Example 2, 148.2 parts of BMA and 162.5 parts of the polysiloxane (a1-1) prepared in Synthesis Example 1 were added. After stirring was performed for five minutes, 27.5 parts of deionized water was added thereto and stirring was performed at 80° C. for four hours to induce a hydrolysis condensation reaction between the reaction product and the polysiloxane. The resultant reaction product was distilled at a reduced pressure of 10 to 300 kPa at 40° C. to 60° C. for two hours, whereby generated methanol and water were removed. Consequently, 600 parts of composite resin (A-1) having a non-volatile content of 72% and including a polysiloxane segment (a1-1) and a vinyl-based polymer segment (a2-1) was obtained.

### Synthesis Example 4

### Preparation Example of Composite Resin (A-2)

To 307 parts of the vinyl-based polymer (a2-1) prepared in Synthesis Example 2, 148.2 parts of BMA and 562.5 parts of the polysiloxane (a1-1) prepared in Synthesis Example 1 were added. After stirring was performed for five minutes, 27.5 parts of deionized water was added thereto and stirring was performed at 80° C. for four hours to induce a hydrolysis condensation reaction between the reaction product and the polysiloxane. The resultant reaction product was distilled at a reduced pressure of 10 to 300 kPa at 40° C. to 60° C. for two hours, whereby generated methanol and water were removed. Consequently, 857 parts of composite resin (A-2) having a non-volatile content of 72% and including a polysiloxane segment (a1-1) and a vinyl-based polymer segment (a2-1) was obtained.

### Examples 1 to 13

In Examples, the processes described below were performed, and Tables 1 to 8 show the compositions and results.

### (Preparation of Cured Product of Sealing Material for Light-Emitting Diode by Heat Curing)

Using the composite resins prepared in Synthesis Examples, raw materials were mixed with each other in accordance with the “Mixing ratio of composition” shown in Tables 1 and 2 to prepare a resin composition for forming a sealing material for light-emitting diodes. The thermosetting sealing materials for light-emitting diodes correspond to the sealing materials in Examples 1 to 6.

Subsequently, a container into which a sealing material is injected (refer to FIG. 2) was fabricated by the following method. A spacer 7 (length: 5 cm, width: 5 cm, height: 2 mm) of a silicon mold was provided so as to be sandwiched between a glass 8 and a glass 9 (the glass 8 and glass 9 each have a length of 10 cm, a width of 10 cm, and a thickness of 4 mm) and between a PET film 10 and a PET film 11. The PET film 10 was disposed between the glass 8 and the spacer 7 and the PET film 11 was disposed between the glass 9 and the spacer 7.

The prepared resin composition for forming a sealing material for light-emitting diodes was poured into the spacer 7, and the glass 8 and the glass 9 were fixed using a jig (not shown) (the obtained mold is referred to as a mold 13). The mold 13 was then inserted into an oven at 150° C. and heated for five minutes to cure the resin composition for forming a sealing material for light-emitting diodes. The cured product 12 was removed from the mold to obtain each of cured products (C-1) to (C-6) and (HC-1) to (HC-4) having a thickness of 2 mm.

### (Preparation of Cured Product of Sealing Material for Light-Emitting Diode by Ultraviolet Curing)

Using the composite resins prepared in Synthesis Examples, raw materials were mixed with each other in accordance with the “Mixing ratio of composition” shown in Tables 1 and 2 to prepare a resin composition for forming a sealing material for light-emitting diodes. The ultraviolet-curable sealing material for light-emitting diodes corresponds to the sealing material in Example 7.

The resin composition for forming a sealing material for light-emitting diodes was injected into the same container as that (refer to FIG. 2) used in the “preparation of cured product of sealing material for light-emitting diode by heat curing”. The entire container was irradiated with ultraviolet rays at 1000 mJ/cm² using a UV irradiation apparatus F-6100V manufactured by FUSION UV SYSTEMS, Inc. to cure the composition. The cured product was removed from the mold to obtain a cured product (C-7) having a thickness of 2 mm.

### (Preparation of Sheet-Shaped Resin Composition for Forming Sealing Material for Solar Cell)

Using the composite resins prepared in Synthesis Examples, raw materials were mixed with each other in accordance with the “Mixing ratio of composition” shown in Tables 1 and 2 to prepare a resin composition for forming a sealing material for solar cells. The resin compositions for forming a sealing material for solar cells correspond to the resin compositions in Examples 1 to 6. The resin composition for forming a sealing material for solar cells was injected into a square-shaped stainless container, and the container was inserted into an oven at 80° C. for one hour to bring the resin composition in a gel state. The resin composition for forming a sealing material for solar cells in a gel state was then calendered at 70° C. and cooled to obtain each of sheet-shaped resin compositions for forming a sealing material for solar cells (PC-1) to (PC-6) and (HPC-1) to (HPC-4) (thickness: 0.6 mm).

### (Production of Solar Cell Module)

The temperature of a hot plate of a laminating machine (manufactured by Nisshinbo Mechatronics Inc.) was adjusted to 150° C. A white tempered glass, the sheet-shaped resin composition for forming a sealing material for solar cells, a polycrystalline silicon solar cell, the sheet-shaped resin composition for forming a sealing material for solar cells, and a PFA film having a thickness of 500 μm and serving as a back sheet were stacked on the hot plate in that order. After the cover of the laminating machine was closed, degassing was performed for three minutes and pressing was performed for eight minutes. The state after the pressing was maintained for ten minutes and then each of superstrate solar cell modules (SM-1) to (SM-6) and (HSM-1) to (HSM-4) was taken out.

(Production of Light-Emitting Diode with Thermosetting Sealing Material)

A light-emitting diode that includes an InGaN-based light-emitting element and is shown in FIG. 3 was produced.

In the drawing, 1 denotes a resin case, 2 denotes a lead electrode, 3 denotes a light-emitting element, 4 denotes a sealing material, and 5 denotes a gold wire.

Using the composite resins prepared in Synthesis Examples, raw materials were mixed with each other in accordance with the “Mixing ratio of composition” of Examples 2 and 3 and Comparative Examples 2 and 3 shown in Tables 1 and 2 to prepare a resin composition for forming a thermosetting sealing material for light-emitting diodes. The resin composition was poured into a resin case (made of PPA: polyphthalamide) so that the thickness of a cured product was 0.5 to 1.0 mm. The resin composition was then cured by performing heating in an oven at 150° C. for five minutes to produce each of light-emitting diodes (M−1), (M-2), (HM-1), and (HM-2).

(Production of Light-Emitting Diode with Ultraviolet-Curable Sealing Material)

A light-emitting diode that includes an InGaN-based light-emitting element and is shown in FIG. 3 was produced. The resin composition for forming an ultraviolet-curable sealing material for light-emitting diodes, the resin composition being prepared in accordance with Example 7, was poured into a resin case (made of PPA: polyphthalamide) so that the thickness of a cured product was 0.5 to 1.0 mm. The resin composition was irradiated with ultraviolet rays at 1000 mJ/cm² using a UV irradiation apparatus F-6100V manufactured by FUSION UV SYSTEMS, Inc. to cure the composition. Thus, a light-emitting diode (M-3) was produced.

### (Evaluation Methods)

### (Evaluation of Curing Property)

A PP sheet having a size of 10 cm×1 cm×2 mm in thickness was pressed against the surface of each of the cured products (C-1) to (C-7) and (HC-1) to (HC-4). The adhesion between the PP sheet and the cured product when the sheet was lifted up was evaluated. When the curing property was good and thus the PP sheet did not adhere to the cured product, an evaluation of Good was given. When the curing property was poor and thus the cured product was raised together with the PP sheet, an evaluation of Poor was given.

(Light Resistance: Evaluation of Degree of Yellowing after Accelerated Fading Test)

Each of the cured products (C-1) to (C-7) and (HC-1) to (HC-4) prepared by the above-described method was subjected to an accelerated fading test at a UV irradiation intensity of 100 mW/cm² using an accelerated UV degradation tester (EYE Super UV Tester SUV-W131 manufactured by IWASAKI ELECTRIC CO., LTD.). The degree of yellowing of the cured product after about 200 hours of the accelerated test was evaluated by measuring a b value, which indicates the degree of yellow in the Lab color space, using a colorimeter manufactured by GretagMacbeth. The degree of yellowing was evaluated as follows. When the difference Δb between a b value before the test and a b value after the test was 0 to 0.5, an evaluation of Excellent was given. When the difference Δb was 0.5 to 1, an evaluation of Good was given. When the difference Δb was 1 to 5, an evaluation of Fair was given. When the difference Δb was 5 or more, an evaluation of Poor was given.

Tables 3 and 4 show the results.

### (Crack Resistance: Thermal Shock Test)

Each of the cured products (C-1) to (C-7) and (HC-1) to (HC-4) was inserted into a small thermal shock tester TSE-11 manufactured by ESPEC Corp. Ten cycles of −40° C.×15 min-120° C.×15 min were performed and the state of cracks formed was evaluated through visual inspection. Table 3 shows the results. When no cracks were observed, an evaluation of Good was given. When cracks were observed, an evaluation of Poor was given. When fractures were observed, an evaluation of Very Poor was given.

### (Evaluation Method: Evaluation of Generation Efficiency of Solar Cell Module)

Regarding the solar cell modules (SM-1) to (SM-6) and (HSM-1) to (HSM-4), the generation efficiency was measured using Solar Simulator manufactured by WACOM ELECTRIC CO., LTD. under the conditions: module temperature 25° C., radiant intensity 1 kW/m², and spectral distribution AM 1.5 G.

Tables 5 and 6 show the results.

(Light Resistance of Light-Emitting Diode: Evaluation of Appearance after Accelerated Fading Test)

Each of the light-emitting diodes (M-1) to (M-3) and (HM-1) and (HM-2) produced by the above-described method was subjected to an accelerated fading test at a UV irradiation intensity of 100 mW/cm² using an accelerated UV degradation tester (EYE Super UV Tester SUV-W131 manufactured by IWASAKI ELECTRIC CO., LTD.). After 200 hours of the accelerated test, when there were no fractures or cracks on the sealing material and the sealing material was not detached from the resin case, an evaluation of Good was given. When there were one or two fractures or cracks, an evaluation of Fair was given. When there were many fractures or cracks or the sealing material was detached from the resin case, an evaluation of Poor was given. Tables 7 and 8 show the results.

### (Evaluation of Heat Resistance of Light-Emitting Diode)

Each of the light-emitting diodes (M−1) to (M-3) and (HM-1) and (HM-2) produced by the above-described method was stored at 120° C. at normal humidity (FineOven DHS72: Yamato Scientific Co., Ltd.) for 500 hours, and then the appearance and yellowing were evaluated as follows. Regarding the appearance, when there were no fractures or cracks on the sealing material and the sealing material was not detached from the resin case, an evaluation of Good was given. When there were one or two fractures or cracks, an evaluation of Fair was given. When there were many fractures or cracks or the sealing material was detached from the resin case, an evaluation of Poor was given. Regarding the yellowing, when yellowing could be confirmed through visual inspection, an evaluation of Poor was given. When yellowing could not be confirmed, an evaluation of Good was given. Tables 7 and 8 show the results.

### (Evaluation of Wet Heat Resistance of Light-Emitting Diode)

Each of the light-emitting diodes (M-1) to (M-3) and (HM-1) and (HM-2) produced by the above-described method was stored in a thermo-hygrostat (LH20-11M: NAGANO SCIENCE CO., LTD.) at 85° C. and 85% RH for 240 hours, and then the appearance and yellowing/whitening were evaluated as follows. Regarding the appearance, when there were no fractures or cracks on the sealing material and the sealing material was not detached from the resin case, an evaluation of Good was given. When there were one or two fractures or cracks, an evaluation of Fair was given. When there were many fractures or cracks or the sealing material was detached from the resin case, an evaluation of Poor was given. Regarding the yellowing/whitening, when yellowing/whitening could be confirmed through visual inspection, an evaluation of Poor was given. When yellowing/whitening could not be confirmed, an evaluation of Good was given. Tables 7 and 8 show the results.

TABLE 1

| | Example | Example | Example | Example | Example | Example | Example |
|---|---|---|---|---|---|---|---|
| | 1 | 2 | 3 | 4 | 5 | 6 | 7 |
| Composite resin A-1 | 68.9 | 68.9 | | 68.9 | 68.9 | 68.9 | 68.9 |
| Composite resin A-2 | | | 68.9 | | | | |
| Diluted monomer 1 | 12.4 | 120.0 | | 12.4 | 12.4 | | 12.4 |
| Diluted monomer 2 | | | | | | 12.4 | |
| Thermal polymerization | 0.9 | 0.9 | 0.9 | 0.9 | 0.9 | 0.9 | |
| initiator | | | | | | | |
| Photopolymerization initiator | | | | | | | 0.3 |
| Polymerization inhibitor | 1.8 | 1.8 | 1.8 | 1.8 | 1.8 | 1.8 | 1.8 |
| Additive | 0.9 | 0.9 | 0.9 | 0.9 | 0.9 | 0.9 | 0.9 |
| Polyisocyanate | 15.1 | 35.0 | 5.0 | 5.0 | 80.0 | 15.1 | 15.1 |
| Content of a1 in composite | 50 | 50 | 75 | 50 | 50 | 50 | 50 |
| resin | | | | | | | |
| Content (%) of a1 relative to | 25.1 | 11.1 | 48.7 | 28.0 | 15.3 | 25.1 | 25.4 |
| total solid content | | | | | | | |
| Content of polyisocyanate | 15.1 | 15.4 | 6.5 | 5.6 | 48.5 | 15.1 | 15.2 |

TABLE 2

| | Comparative | Comparative | Comparative | Comparative |
|---|---|---|---|---|
| | Example 1 | Example 2 | Example 3 | Example 4 |
| Composite resin A-1 | 68.9 | | 68.9 | 68.9 |
| Composite resin A-2 | | 140.0 | | |
| Diluted monomer 1 | 170.0 | | 12.4 | 12.4 |
| Diluted monomer 2 | | | | |
| Thermal polymerization initiator | 0.9 | 0.9 | 0.9 | 0.9 |
| Photopolymerization initiator | | | | |
| Polymerization inhibitor | 1.8 | 1.8 | 1.8 | 1.8 |
| Additive | 0.9 | 0.9 | 0.9 | 0.9 |
| Polyisocyanate | 35.0 | 8.0 | 4.0 | 100.0 |
| Content of a1 in composite resin | 50 | 75 | 50 | 50 |
| Content (%) of a1 relative to total | 9.1 | 50.6 | 28.3 | 13.6 |
| solid content | | | | |
| Content of polyisocyanate | 12.6 | 5.3 | 4.5 | 54.1 |

The raw materials in Tables 1 and 2 are shown below.

Diluted monomer 1: 1,6-hexanediol diacrylate
Diluted monomer 2: methyl methacrylate
Thermal polymerization initiator: t-butylperoxybenzoate
Photopolymerization initiator: diphenyl(2,4,6-trimethoxybenzoyl)phosphine oxide
Polymerization inhibitor: 2,6-bis(1,1-dimethylethyl)-4-methylphenol
Additive: 3-methacryloxypropyltrimethoxysilane
Polyisocyanate: BURNOCK DN-902S manufactured by DIC Corporation

TABLE 3

| | Example 1 | Example 2 | Example 3 | Example 4 | Example 5 | Example 6 | Example 7 |
|---|---|---|---|---|---|---|---|
| Name of cured | C-1 | C-2 | C-3 | C-4 | C-5 | C-6 | C-7 |
| product | | | | | | | |
| Curing property | Good | Good | Good | Good | Good | Good | Good |
| Δb | Excellent | Good | Excellent | Excellent | Good | Excellent | Excellent |
| Thermal shock test | Good | Good | Good | Good | Good | Good | Good |

TABLE 4

| | Comparative | Comparative | Comparative | Comparative |
|---|---|---|---|---|
| | Example 1 | Example 2 | Example 3 | Example 4 |
| Name of cured | HC-1 | HC-2 | HC-3 | HC-4 |
| product | | | | |
| Curing | Good | Good | Good | Poor |
| property | | | | |
| Δb | Fair | Excellent | Excellent | Good |
| Thermal shock | Good | Poor | Poor | Good |
| test | | | | |

TABLE 5

| | Example 8 | Example 9 | Example 10 | Example 11 | Example 12 | Example 13 |
|---|---|---|---|---|---|---|
| Resin composition | Example 1 | Example 2 | Example 3 | Example 4 | Example 5 | Example 6 |
| Name of sealing material | PC-1 | PC-2 | PC-3 | PC-4 | PC-5 | PC-6 |
| for solar cells | | | | | | |
| Δb | Excellent | Good | Excellent | Excellent | Good | Excellent |
| Thermal shock test | Good | Good | Good | Good | Good | Good |
| (Name of superstrate module) | (SM-1) | (SM-2) | (SM-3) | (SM-4) | (SM-5) | (SM-6) |
| Generation efficiency (%) | 10.4 | 10.3 | 10.3 | 10.3 | 10.4 | 10.5 |

TABLE 6

| | Comparative | Comparative | Comparative | Comparative |
|---|---|---|---|---|
| | Example 5 | Example 6 | Example 7 | Example 8 |
| Resin | Comparative | Comparative | Comparative | Comparative |
| composition | Example 1 | Example 2 | Example 3 | Example 4 |
| Name of | HPC-1 | HPC-2 | HPC-3 | HPC-4 |
| sealing | | | | |
| material for | | | | |
| solar cells | | | | |
| Δb | Fair | Excellent | Excellent | Good |
| Thermal shock | Good | Poor | Poor | Good |
| test | | | | |
| (Name of | (HSM-1) | (HSM-2) | (HSM-3) | (HSM-4) |
| superstrate | 10.4 | 10.3 | 10.3 | Cell fracture |
| module) | | | | |
| Generation | | | | |
| efficiency (%) | | | | |

TABLE 7

| | | Example 14 | Example 15 | Example 16 |
|---|---|---|---|---|
| Resin composition | | Example 3 | Example 4 | Example 7 |
| Light-emitting diode | | M-1 | M-2 | M-3 |
| Fading test | | Good | Good | Good |
| Heat resistance | Appearance | Good | Good | Good |
| | Yellowing | Good | Good | Good |
| Wet heat | Appearance | Good | Good | Good |
| resistance | Yellowing/ | Good | Good | Good |
| | Whitening | | | |

TABLE 8

| | | Comparative | Comparative |
|---|---|---|---|
| | | Example 9 | Example 10 |
| Composition | | Comparative | Comparative |
| | | Example 2 | Example 3 |
| Light-emitting diode | | HM-1 | HM-2 |
| Fading test | | Poor | Fair |
| Heat resistance | Appearance | Fair | Poor |
| | Yellowing | Good | Good |
| Wet heat | Appearance | Fair | Fair |
| resistance | Yellowing/Whitening | Good | Good |

### REFERENCE SIGNS LIST

1 protective sheet for solar cells
2 first sealing material
3 group of solar cells
4 second sealing material
5 backside protective sheet
7 spacer
8 glass
9 glass
10 PET film
11 PET film
12 cured product
13 mold
14 resin case
15 lead electrode
16 light-emitting element
17 sealing material
18 gold wire

1. A sealing material comprising a composite resin (A) including a polysiloxane segment (a1) having a structural unit represented by general formula (1) and/or general formula (2) and a silanol group and/or a hydrolyzable silyl group and a vinyl-based polymer segment (a2) having an alcoholic hydroxyl group, the vinyl-based polymer segment (a2) being bonded to the polysiloxane segment (a1) through a bond represented by general formula (3), and a polyisocyanate (B), wherein the content of the polysiloxane segment (a1) is 10% to 50% by weight relative to the total solid content of a curable resin composition, and the content of the polyisocyanate (B) is 5% to 50% by weight relative to the total solid content of the curable resin composition: 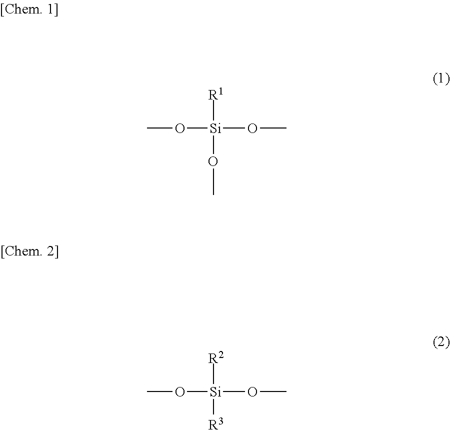
(in the general formulae (1) and (2), R¹, R², and R³ each independently represent a group having a polymerizable double bond selected from the group consisting of —R⁴—CH═CH₂, —R⁴—C(CH₃)═CH₂, —R⁴—O—CO—C(CH₃)═CH₂, and —R⁴—O—CO—CH═CH₂ (R⁴ represents a single bond or an alkylene group having 1 to 6 carbon atoms), an alkyl group having 1 to 6 carbon atoms, a cycloalkyl group having 3 to 8 carbon atoms, an aryl group, or an aralkyl group having 7 to 12 carbon atoms, and at least one of R¹, R², and R³ represents the group having a polymerizable double bond), 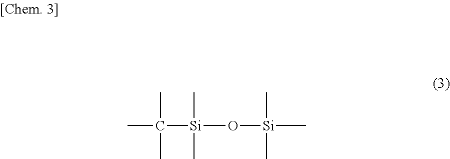
(in the general formula (3), a carbon atom constitutes a part of the vinyl-based polymer segment (a2) and a silicon atom bonded to only an oxygen atom constitutes a part of the polysiloxane segment (a1)).

2. The sealing material according to claim 1 used for a solar cell.

3. The sealing material according to claim 1 used for a light-emitting diode.

4. A solar cell module that uses the sealing material according to claim 1.

5. A light-emitting diode that uses the sealing material according to claim 1.

6. A solar cell module that uses the sealing material according to claim 2.

7. A light-emitting diode that uses the sealing material according to claim 3.
